(19) United States
(12) Patent Application Publication
(10) Pub. No.: US 2025/0234508 A1
(43) Pub. Date: Jul. 17, 2025

(54) SEMICONDUCTOR DEVICE AND ELECTRONIC DEVICE

(71) Applicant: SAMSUNG ELECTRONICS CO., LTD., Suwon-si (KR)

(72) Inventors: Keun Wook SHIN, Suwon-si (KR); SANGWOOK KIM, Suwon-si (KR); Sangwon KIM, Suwon-si (KR); Jungkyun Kim, Suwon-si (KR); JEEEUN YANG, Suwon-si (KR)

(21) Appl. No.: 18/921,483

(22) Filed: Oct. 21, 2024

(30) Foreign Application Priority Data
Jan. 16, 2024 (KR) 10-2024-0006980

(51) Int. Cl. H10B 12/00

(52) U.S. Cl. CPC H10B 12/315

(57) ABSTRACT

A semiconductor device includes an oxide semiconductor layer including an oxide semiconductor, a conductive layer, and a buffer layer disposed between the oxide semiconductor layer and the conductive layer, where the buffer layer includes graphene.

### CROSS-REFERENCE TO RELATED APPLICATION

This application claims priority to Korean Patent Application No. 10-2024-0006980, filed on Jan. 16, 2024, and all the benefits accruing therefrom under 35 U.S.C. § 119, the content of which in its entirety is herein incorporated by reference.

### BACKGROUND

### 1. Field

Embodiments of the disclosure relate to a semiconductor device and an electronic device including the semiconductor device.

### 2. Description of the Related Art

As the demand for various digital devices increases, the demand for integrated circuit devices is also rapidly increasing. Recently, as the degree of integration of integrated circuit devices continues to increase, research is being conducted on semiconductor devices with new structures that reduce the area of a unit cell.

### SUMMARY

An embodiment provides a semiconductor device capable of improving electrical characteristics while having a new structure that reduces an area of a unit cell.

Another embodiment provides an electronic device including the semiconductor device.

According to an embodiment, a semiconductor device includes an oxide semiconductor layer including an oxide semiconductor, a conductive layer, and a buffer layer between the oxide semiconductor layer and the conductive layer, where the buffer layer includes graphene.

In an embodiment, the buffer layer may be in contact with a surface of the oxide semiconductor layer and a surface of the conductive layer, respectively.

In an embodiment, the graphene may include nanocrystalline graphene with a plurality of crystalline grains.

In an embodiment, the buffer layer may further include metal nanoparticles distributed in at least one selected from an upper portion, a lower portion, and an inner portion of the buffer layer.

In an embodiment, each of the metal nanoparticles may include at least one selected from ruthenium (Ru), aluminum (Al), copper (Cu), hafnium (Hf), iridium (Ir), rhodium (Rh), tungsten (W), molybdenum (Mo), titanium (Ti), tantalum (Ta), iron (Fe), cobalt (Co), iridium (Ir), palladium (Pd), platinum (Pt), and osmium (Os).

In an embodiment, a thickness of the buffer layer may be in a range of about 0.3 nanometer (nm) to about 5 nm.

In an embodiment, the oxide semiconductor may include an oxide including at least one selected from indium (In), zinc (Zn), gallium (Ga), and tin (Sn).

In an embodiment, the conductive layer may include at least one selected from tungsten (W), ruthenium (Ru), copper (Cu), molybdenum (Mo), aluminum (Al), hafnium (Hf), cobalt (Co), titanium (Ti), tantalum (Ta), nickel (Ni), palladium (Pd), platinum (Pt), chromium (Cr), iron (Fe), rhodium (Rh), iridium (Ir), and osmium (Os).

In an embodiment, the semiconductor device may include a transistor channel and a wire or electrode, the transistor channel may include the oxide semiconductor layer, and the wire or electrode may include the conductive layer.

According to another embodiment, a semiconductor device includes a semiconductor substrate, a transistor channel extending perpendicular to an in-plane direction of the semiconductor substrate, where the transistor channel includes an oxide semiconductor, a bit line under the transistor channel and electrically connected to the transistor channel, and a buffer layer between the transistor channel and the bit line, where the buffer layer includes graphene.

In an embodiment, the graphene may include nanocrystalline graphene having a plurality of crystalline grains.

In an embodiment, the buffer layer may further include metal nanoparticles disposed in at least one selected from an upper portion, a lower portion, and an inner portion of the buffer layer.

In an embodiment, each of the metal nanoparticles may include at least one selected from ruthenium (Ru), aluminum (Al), copper (Cu), hafnium (Hf), iridium (Ir), rhodium (Rh), tungsten (W), molybdenum (Mo), titanium (Ti), tantalum (Ta), iron (Fe), cobalt (Co), iridium (Ir), palladium (Pd), platinum (Pt), and osmium (Os).

In an embodiment, a thickness of the buffer layer may be in a range of about 0.3 nm to about 5 nm.

In an embodiment, the oxide semiconductor may include an oxide including at least one selected from indium (In), zinc (Zn), gallium (Ga), and tin (Sn).

In an embodiment, the bit line may include at least one selected from tungsten (W), ruthenium (Ru), copper (Cu), molybdenum (Mo), aluminum (Al), hafnium (Hf), cobalt (Co), titanium (Ti), tantalum (Ta), nickel (Ni), palladium (Pd), platinum (Pt), chromium (Cr), iron (Fe), rhodium (Rh), iridium (Ir), and osmium (Os).

In an embodiment, the semiconductor device may further include a word line disposed on the semiconductor substrate and extending in a direction different from an extending direction of the bit line, a gate electrode electrically connected to the word line and extending perpendicular to an in-plane direction of the semiconductor substrate, and a gate insulating film between the gate electrode and the transistor channel.

In an embodiment, the semiconductor device may further include a capacitor disposed on the transistor channel and electrically connected to the transistor channel.

According to another embodiment, an electronic device including the semiconductor device is provided.

In embodiments, the electrical characteristics of semiconductor devices with a new structure that reduces the area of the unit cell may be improved.

### BRIEF DESCRIPTION OF THE DRAWINGS

FIG. 1 is a cross-sectional view schematically showing an example of a semiconductor device according to an embodiment,

FIGS. 2 to 4 are schematic views showing examples of buffer layers in the semiconductor device of FIG. 1, respectively,

FIG. 5 is a plan view showing an example of a semiconductor device according to another embodiment,

FIG. 6 is a perspective view showing an example of the semiconductor device of FIG. 5,

FIGS. 7 to 9 are schematic views showing an example of a transistor of the semiconductor device of FIG. 5, respectively, and FIG. 10 is a conceptual diagram showing an example of an electronic device according to an embodiment.

### DETAILED DESCRIPTION

The disclosure now will be described more fully hereinafter with reference to the accompanying drawings, in which various embodiments are shown. This disclosure may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the drawings, the thickness of layers, films, panels, regions, etc., are exaggerated for clarity and like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

The drawings and description are to be regarded as illustrative in nature and not restrictive. Like reference numerals designate like elements throughout the specification.

It will be understood that when a component is referred to as being “on” or “above” another component, the component can be directly on, under, on the left of, or on the right of the other component, or can be on, under, on the left of, or on the right of the other component in a non-contact manner. In addition, unless explicitly described to the contrary, the word “comprise,” and variations such as “comprises” or “comprising,” will be understood to imply the inclusion of stated elements.

The term “layer” includes a construction having a shape formed on a part of a region, in addition to a construction having a shape formed on an entire region.

The steps of all methods described herein can be performed in any suitable order unless otherwise indicated herein or otherwise clearly contradicted by context.

Here, “combination thereof” refer to a mixture, a stacked structure, a composite, an alloy, or a blend of constituents.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Hereinafter, unless otherwise defined, “substantially” or “approximately” or “about” includes not only the stated value, but also the average within an allowable range of deviation, considering the error associated with the measurement and amount of the measurement. For example, “substantially” or “approximately” may mean within ±10%, ±5%, ±3%, or ±1% of the indicated value or within a standard deviation.

Hereinafter, “metal” is interpreted as a concept including metals and metalloids (semi-metals).

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of a semiconductor device according to embodiments will be described with reference to the accompanying drawings.

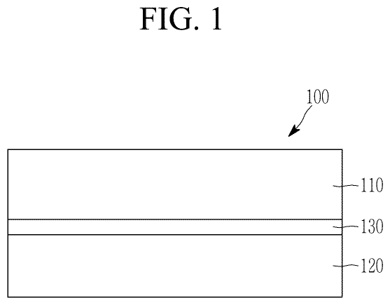

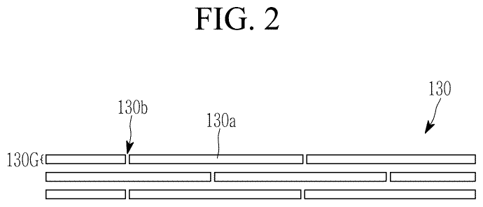

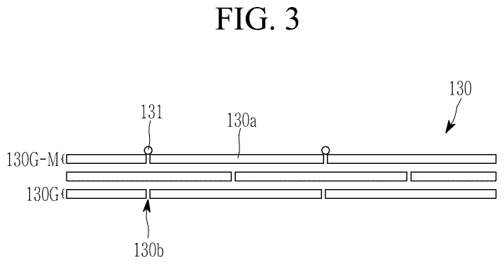

FIG. 1 is a cross-sectional view schematically showing an example of a semiconductor device according to an embodiment, and FIGS. 2 to 4 are schematic views showing examples of buffer layers in the semiconductor device of FIG. 1, respectively.

Referring to FIG. 1, an example of a semiconductor device 100 according to an embodiment includes an oxide semiconductor layer 110, a conductive layer 120, and a buffer layer 130.

The oxide semiconductor layer 110 may be an active layer that exhibits semiconductor characteristics. In an embodiment, for example, where the semiconductor device 100 includes a transistor, the oxide semiconductor layer 110 may be a transistor channel. The oxide semiconductor layer 110 may include an oxide semiconductor including at least one metal and/or semi-metal, for example, an oxide including at least one selected from indium (In), zinc (Zn), gallium (Ga), and tin (Sn).

In an embodiment, the oxide semiconductor may include, for example, zinc oxide, gallium oxide, indium-gallium oxide (In-Ga oxide), zinc-tin oxide (Zn-Sn oxide), indium-gallium-zinc oxide (In-Ga-Zn oxide) or a combination thereof, but is not limited thereto.

In such an embodiment, the zinc oxide or gallium oxide may be an oxide including zinc (Zn) or gallium (Ga) as a main component, and may further include one or more other elements (e.g., metal or semi-metal) in addition to zinc (Zn) or gallium (Ga) as a dopant.

In such an embodiment, the indium-gallium oxide or zinc-tin oxide may be an oxide including In/Ga or Zn/Sn as main components, and may further include one or more other elements (e.g., metal or semi-metal) as a dopant in addition to In/Ga or Zn/Sn.

In such an embodiment, the indium-gallium-zinc oxide may be an oxide including In/Ga/Zn as main components, and may further include one or more other elements (e.g., metal or semi-metal) as dopants in addition to In/Ga/Zn.

The conductive layer 120 may include a conductive wire or electrode. The conductive layer 120 may include a low-resistance metal or an alloy thereof with relatively low resistance, for example, tungsten (W), ruthenium (Ru), copper (Cu), molybdenum (Mo), aluminum (Al), Hafnium (Hf), cobalt (Co), titanium (Ti), tantalum (Ta), nickel (Ni), palladium (Pd), platinum (Pt), chromium (Cr), iron (Fe), rhodium (Rh), iridium (Ir), osmium (Os), an alloy thereof, or a combination thereof, but is not limited thereto.

The buffer layer 130 may be between the oxide semiconductor layer 110 and the conductive layer 120. In an embodiment, for example, one surface of the buffer layer 130 may be in contact with the oxide semiconductor layer 110, and another surface (e.g., an opposite surface of the one surface) of the buffer layer 130 may be in contact with the conductive layer 120. In an embodiment, for example, the buffer layer 130 may be in contact with a surface (e.g., a lower surface) of the oxide semiconductor layer 110 and a surface (e.g., an upper surface) of the conductive layer 120, respectively. In an embodiment, for example, the buffer layer 130 may be in contact with the entire lower surface of the oxide semiconductor layer 110.

The buffer layer 130 may be below the oxide semiconductor layer 110 and may block direct contact between the conductive layer 120 and the oxide semiconductor layer 110. Accordingly, it is possible to effectively prevent the conductive layer 120 from being oxidized by the oxide semiconductor during a formation process of the oxide semiconductor layer 110, subsequent processes, and/or the operation process of the semiconductor device 100.

Referring to FIG. 2, in an embodiment, the buffer layer 130 includes graphene 130G. The graphene 130G may be a substantially two-dimensional conductive material with a very thin thickness of several angstroms. Here, the graphene 130G may be defined as a layer in which several graphene monolayers are stacked. In an embodiment, the buffer layer 130 may include n layers, each layer including or made of the graphene 130G. Herein, n may be, for example, an integer of 1 to 10, but is not limited thereto.

At least a portion of the graphene 130G may include nanocrystalline graphene. As shown in FIG. 2, the graphene 130G including nanocrystalline graphene may include a grain boundary 130b between a plurality of crystalline grains 130a having a size (e.g., a lateral size) of several to tens of nanometers and adjacent crystalline grains 130a. In an embodiment, for example, an average size (e.g., average lateral size) of the plurality of crystalline grains 130amay be in a range of about 0.5 nanometers (nm) to about 100 nm, e.g., in a range of about 0.5 nm to about 80 nm, in a range of about 1 nm to about 80 nm, or in a range of about 1 nm to about 60 nm.

The graphene 130G including nanocrystalline graphene, unlike intrinsic graphene, may have less than about 100% of a ratio of carbon having a sp² bond, for example, less than or equal to about 99%, or for example, about 50% to about 99% based on total carbon. The graphene 130G including nanocrystalline graphene may include hydrogen in addition to the carbon, where the hydrogen may be, for example, included in an amount in a range of about 1 atomic percent (at %) to about 20 at % based on the total number of atoms. The graphene 130G including nanocrystalline graphene may have lower density than the intrinsic graphene, for example, density of less than or equal to about 2.1 grams per cubic centimeter (g/cc), for example, in a range of about 1.6 g/cc to about 2.1 g/cc.

The graphene 130G including nanocrystalline graphene may be deposited and/or grown at a relatively lower temperature than the intrinsic graphene, for example, at a temperature less than or equal to about 700° C., less than or equal to about 600° C., for example, at a temperature less than or equal to about 500° C.,, at a temperature in a range of about 200° C. to about 700° C., at a temperature in a range of about 200° C. to about 600° C., or at a temperature in a range of about 200° C. to about 500° C. The deposition may be performed, for example, through chemical vapor deposition (CVD) or plasma enhanced chemical vapor deposition (PECVD), but is not limited thereto.

The buffer layer 130 may have a thickness of, for example, less than about 10 nm, for example, in a range of about 0.3 nm to about 10 nm, in a range of about 0.3 nm to about 8 nm, in a range of about 0.3 nm to about 5 nm, in a range of about 0.3 nm to about 3 nm, in a range of about 0.5 nm to about 10 nm, in a range of about 0.5 nm to about 8 nm, in a range of about 0.5 nm to about 5 nm, or in a range of about 0.5 nm to about 3 nm.

Referring to FIG. 3, in another embodiment, the buffer layer 130 may include metal-doped graphene 130G-M including metal nanoparticles 131. The metal nanoparticles 131 may be distributed in at least one selected from an upper portion, a lower portion, and an inside (or an inner portion) of the buffer layer 130. In an embodiment, for example, the metal-doped graphene 130G-M may be in a portion of the buffer layer 30 from a top surface of the buffer layer 130 to a predetermined depth. In an embodiment, for example, the metal-doped graphene 130G-M may be in a portion of the buffer layer from a bottom surface of the buffer layer 130 to a predetermined height. In an embodiment, for example, the metal-doped graphene 130G-M may be in contact with the oxide semiconductor layer 110 or the conductive layer 120. A portion of the buffer layer 130 may include the graphene 130G that is not doped with metal.

In an embodiment, for example, the metal nanoparticle 131 may be mainly distributed between crystalline grains 130a neighboring each other in each metal-doped graphene 130G-M, that is, at a grain boundary 130b. In such an embodiment, the number of the metal nanoparticles 131 disposed at the grain boundary 130b may be substantially greater than the number of the metal nanoparticles 131 that are not disposed at the grain boundary 130b.

Accordingly, the diffusion of oxide from the oxide semiconductor layer 110 through the grain boundary 130b to the conductive layer 120 may be effectively prevented by the metal nanoparticle 131 to effectively increase a diffusion barrier function of the buffer layer 130 and increase conductivity of the buffer layer 130 itself. Accordingly, the increase in resistance due to oxidation of the conductive layer 120 may be reduced, and overall electrical characteristics of the semiconductor device 100 may be improved.

The shape of the metal nanoparticle 131 is not particularly limited as long as the metal nanoparticle 131 has a particle size (a particle diameter or longitudinal diameter) of, for example, greater than or equal to about 1 nm and less than about 10 nm, and may be, for example, linear, plate-shaped, and/or spherical. The metal nanoparticles 131 may include a low-resistance metal with relatively low resistance, for example, ruthenium (Ru), aluminum (Al), copper (Cu), hafnium (Hf), iridium (Ir), rhodium (Rh), tungsten (W), molybdenum (Mo), titanium (Ti), tantalum (Ta), iron (Fe), cobalt (Co), iridium (Ir), palladium (Pd), platinum (Pt), osmium (Os), an alloy thereof, or a combination thereof, but are not limited thereto.

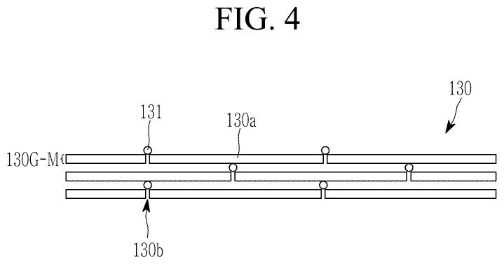

Referring to FIG. 4, the buffer layer 130 may include or be formed of the metal-doped graphene 130G-M including the metal nanoparticles 131, and the metal nanoparticles 131 may be evenly distributed in graphene of the top portion (or an uppermost graphene), graphene of the bottom portion (or a lowermost graphene), and at most of the grain boundary 130b of the graphene therebetween (a middle graphene) in the buffer layer 130. Accordingly, the oxide diffusion from the oxide semiconductor layer 110 through the grain boundary 130b to the conductive layer 120 may be more effectively prevented, and simultaneously, contact resistance between the oxide semiconductor layer 110 and the buffer layer 130 and between the conductive layer 120 and the buffer layer 130 may be effectively reduced. In addition, conductivity of the buffer layer 130 itself may be further increased. Accordingly, the increase in resistance by the oxidation of the conductive layer 120 may be further effectively reduced to further prevent degradation of electrical characteristics, and simultaneously, contact resistance with its neighboring layers may be lowered, while increasing the conductivity of the buffer layer 130 itself, improving overall electrical characteristics of the semiconductor device 100.

The metal nanoparticles 131 may be injected into each graphene 130G of the buffer layer 130, for example, by atomic layer deposition (ALD), to form the metal-doped graphene 130G-M. A content of the metal nanoparticles 131 in the buffer layer 130 may be, for example, adjusted by the number of performing the atomic layer deposition, for example, the atomic layer deposition may be 2 times to 20 times performed for each graphene 130G, for example, 2 times to 15 times, or 5 times to 10 times performed to inject the metal nanoparticles 131. In an embodiment, for example, where the metal nanoparticles 131 may be ruthenium (Ru) nanoparticles, the Ru nanoparticles may be about 2 times and about 10 time injected into the graphene 130G through the atomic layer deposition, such that resistivity of the metal-doped graphene 130G-M may be respectively reduced to about 60% and about 90% of that of the graphene 130G.

In an embodiment, for example, the semiconductor device 100 may include a stack of the conductive layer 120, the buffer layer 130, and the oxide semiconductor layer 110 sequentially formed on a substrate (e.g., semiconductor substrate), and the stack alone or with other components may form the semiconductor device 100.

In an embodiment, as described above, the buffer layer 130 may effectively prevent the oxidation of the conductive layer 120 by diffusion of an oxide semiconductor between the conductive layer 120 and the oxide semiconductor layer 110 to effectively prevent the sharp increase in resistance of the conductive layer 120. Accordingly, degradation of the electrical performance of the semiconductor device 100 may be substantially reduced or effectively prevented.

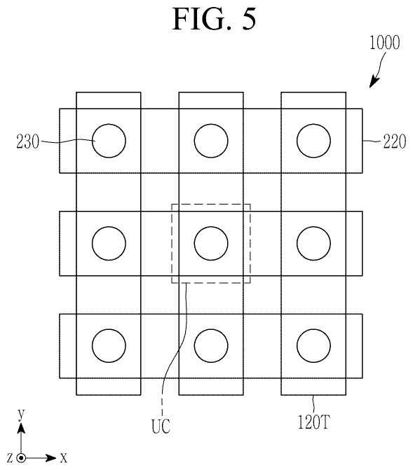

Hereinafter, a semiconductor device according to another embodiment will be described with reference to FIGS. 5 to 9.

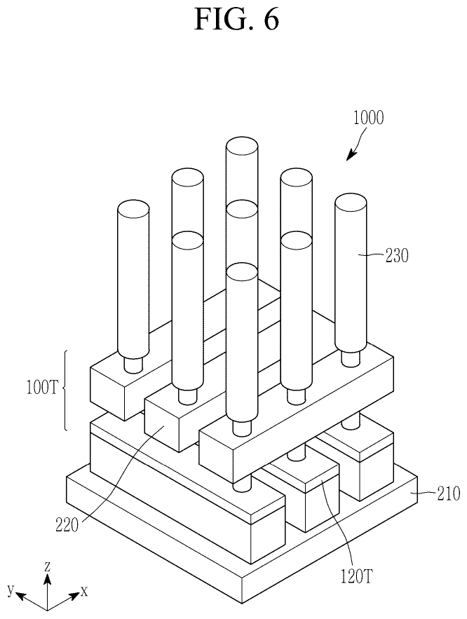

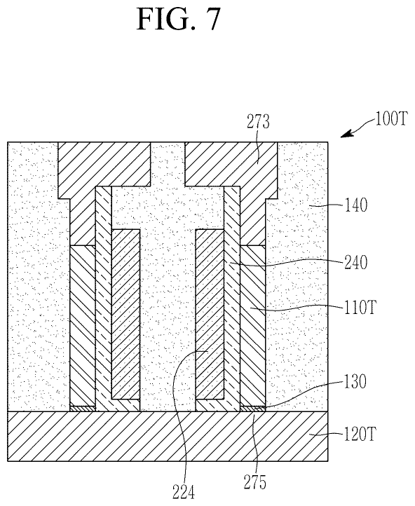

FIG. 5 is a plan view showing an example of a semiconductor device according to another embodiment, FIG. 6 is a perspective view showing an example of the semiconductor device of FIG. 5, and FIGS. 7 to 9 are schematic views showing an example of a transistor of the semiconductor device of FIG. 5, respectively.

Referring to FIGS. 5 and 6, the semiconductor device 1000 according to an embodiment includes a plurality of active regions defined by a plurality of bit lines 120T and a plurality of word lines 220, and a plurality of active regions are arranged in an array. A unit cell UC including a transistor 100T and a capacitor 230 may be disposed in each active region. The semiconductor device 1000 according to an embodiment may be a dynamic random-access memory (DRAM) device.

The semiconductor device 1000 according to an embodiment includes a semiconductor substrate 210, a bit line 120T, a word line 220, a transistor 100T, and a capacitor 230. The semiconductor device 1000 may be, for example, a DRAM device.

The semiconductor substrate 210 may include a Group IV semiconductor material such as silicon (Si), germanium (Ge), silicon-germanium (SiGe), and silicon carbide (SiC); a Group III-V semiconductor material such as GaP, GaAs, and GaSb; or a combination thereof. In an embodiment, for example, the semiconductor substrate 210 may be a silicon-on-insulator (SOI) substrate or a germanium-on-insulator (GOI) substrate.

The bit line 120T and the word line 220 extend in different directions from each other on the semiconductor substrate 210. In an embodiment, for example, the bit line 120T and the word line 220 may be arranged substantially perpendicular to each other. In an embodiment, for example, the bit line 120T may extend in a y direction, and the word line 220 may extend in a x direction.

The bit line 120T and the word line 220 may be disposed at different heights from a surface (e.g., an upper surface) of the semiconductor substrate 210. In an embodiment, for example, the bit line 120T may be disposed closer to the surface of the semiconductor substrate 210 than the word line 220.

The bit line 120T and the word line 220 are each electrically connected to a transistor 100T, which will be described later. The bit line 120T and the word line 220 may each include a low-resistance metal with relatively low resistance, for example, tungsten (W), ruthenium (Ru), copper (Cu), molybdenum (Mo), aluminum (Al), Hafnium (Hf), cobalt (Co), titanium (Ti), tantalum (Ta), nickel (Ni), palladium (Pd), platinum (Pt), chromium (Cr), iron (Fe), rhodium (Rh), iridium (Ir), osmium (Os), an alloy thereof, or a combination thereof, but are not limited thereto.

The transistor 100T may be disposed in an active region defined by the bit line 120T and the word line 220 on the semiconductor substrate 210, and may be repeatedly arranged along rows and/or columns on the semiconductor substrate 210 to form a transistor array. The transistor 100T may be a vertical channel array transistor (VCAT) in which the transistor channel 110T extends perpendicular to an in-plane direction (e.g., xy direction) of the semiconductor substrate 210, that is, in a z direction. In such an embodiment, the transistor channel 110T may extend in a direction perpendicular to a plane defined by the x direction and the y direction. Each transistor 100T may be electrically connected to the bit line 120T, the word line 220, and the capacitor 230 to play a switching role.

Referring to FIG. 7, the transistor 100T according to an embodiment includes a transistor channel 110T, a buffer layer 130, a gate electrode 224, a gate insulating film 240, a source electrode 273, and a drain electrode 275. The transistor 100T may be buried in the insulating film 140.

The transistor channel 110T may extend perpendicular to the in-plane direction (e.g., xy direction) of the semiconductor substrate 210 on the semiconductor substrate 210. In this way, the transistor channel 110T is formed perpendicular to the in-plane direction (for example, xy direction) of the semiconductor substrate 210, so that, compared to a structure in which the transistor channel 110T is formed horizontally on the semiconductor substrate 210 or a structure buried in the semiconductor substrate 210, an area of each unit cell may be effectively reduced and thus more unit cells may be formed on the semiconductor substrate 210. Therefore, a highly integrated semiconductor device 1000 may be implemented.

The transistor channel 110T may be the aforementioned oxide semiconductor layer 110 or may include the oxide semiconductor layer 110. The oxide semiconductor layer 110 may include an oxide semiconductor including at least one metal and/or semi-metal, for example, an oxide including at least one selected from indium (In), zinc (Zn), gallium (Ga), and tin (Sn). In an embodiment, the oxide semiconductor may be, for example, zinc oxide, gallium oxide, indium-gallium oxide (In-Ga oxide), zinc-tin oxide (Zn-Sn oxide), indium-gallium-zinc oxide (In-Ga-Zn oxide) or a combination thereof, but is not limited thereto.

In such an embodiment, the zinc oxide or gallium oxide may be an oxide containing zinc (Zn) or gallium (Ga) as a main component, and may further include one or more other elements (e.g., metal or semi-metal) in addition to zinc (Zn) or gallium (Ga) as a dopant.

In such an embodiment, the indium-gallium oxide or zinc-tin oxide may be an oxide containing In/Ga or Zn/Sn as main components, and may further include one or more other elements (e.g., metal or semi-metal) as a dopant in addition to In/Ga or Zn/Sn.

In such an embodiment, the indium-gallium-zinc oxide may be an oxide including In/Ga/Zn as main components, and may further include one or more other elements (e.g., metal or semi-metal) as dopants in addition to In/Ga/Zn.

The buffer layer 130 may be interposed between the transistor channel 110T and the bit line 120T. The buffer layer 130 may correspond to the above-mentioned buffer layer 130. In such an embodiment, for example, the bit line 120T, the buffer layer 130, and the transistor channel 110T may respectively correspond to the conductive layer 120, the buffer layer 130, and the oxide semiconductor layer 110 described above with reference to FIGS. 1 to 4.

The buffer layer 130 may be disposed between the transistor channel 110T and the bit line 120T, for example, one surface of the buffer layer 130 may be in contact with the transistor channel 110T, while another surface of the buffer layer 130 may be in contact with the bit line 120T. In an embodiment, for example, the buffer layer 130 may be respectively in contact with the lower surface of the transistor channel 110T and the upper surface of the bit line 120T, for example, the buffer layer 130 may be in contact with the entire lower surface of the transistor channel 110T.

The buffer layer 130 may be disposed under the transistor channel 110T to block the bit line 120T from directly contacting the transistor channel 110T. Accordingly, in a forming process of the transistor channel 110T, its subsequent process, and/or an operation process of the semiconductor device 1000, oxidation of the bit line 120T by an oxide semiconductor in the transistor channel 110T may be effectively prevented.

In such an embodiment, referring to FIGS. 1 and 2 with FIG. 7, the buffer layer 130 may include the graphene 130G, for example, n layers, each including or made of the graphene 130G. Here, n may be, for example, an integer of 1 to 10, but is not limited thereto. At least a portion of the graphene 130G may include nanocrystalline graphene, as described above, and any repetitive detailed description thereof will be omitted. The buffer layer 130 may effectively prevent the oxidation of the bit line 120T by the oxide diffusion between the bit line 120T and the transistor channel 110T, and the sharp increase in resistance of the bit line 120T by the oxidation may be effectively prevented. Accordingly, degradation of the electrical performance of the semiconductor device 1000 may be substantially reduced or effectively prevented.

In such an embodiment, referring to FIGS. 1, 3, and 4 with FIG. 7, the buffer layer 130 may include the metal-doped graphene 130G-M including the metal nanoparticles 131. In such an embodiment, the metal nanoparticles 131 may be distributed in at least one selected from an upper portion, a lower portion, and an inside of the buffer layer 130, and mainly at the grain boundary 130b in the metal-doped graphene 130G-M, as described above, and any repetitive detailed description thereof will be omitted. The buffer layer 130 includes the metal nanoparticles 131 distributed at the grain boundary 130b to effectively prevent the oxide diffusion from the transistor channel 110T through the grain boundary 130b to the bit line 120T and thus effectively increase a diffusion barrier function of the buffer layer 130 and also, increase conductivity of the buffer layer 130 itself. Accordingly, the increase in resistance by oxidation of the bit line 120T may be effectively reduced, and overall electrical characteristics of the semiconductor device 1000 may be improved.

The shape of the metal nanoparticle 131 is not particularly limited as long as the metal nanoparticle 131 has a particle size (particle diameter or long diameter) of, for example, greater than or equal to about 1 nm and less than about 10 nm, and may be, for example, linear, plate-shaped, and/or spherical. The metal nanoparticles 131 may include a low-resistance metal with relatively low resistance, for example, ruthenium (Ru), aluminum (Al), copper (Cu), hafnium (Hf), iridium (Ir), rhodium (Rh), tungsten (W), molybdenum (Mo), titanium (Ti), tantalum (Ta), iron (Fe), cobalt (Co), iridium (Ir), palladium (Pd), platinum (Pt), osmium (Os), an alloy thereof, or a combination thereof, but are not limited thereto

The metal nanoparticles 131 may be injected into each graphene 130G of the buffer layer 130 to form metal-doped graphene 130G-M, and may be injected by, for example, atomic layer deposition (ALD).

A content of the metal nanoparticles 131 in the buffer layer 130 may be adjusted, for example, by the number of performing atomic layer depositions. In an embodiment, for example, each graphene 130G may be injected by atomic layer deposition 2 to 20 times, for example, may be injected by atomic layer deposition 2 to 15 times or 5 to 10 times. In an embodiment, for example, where the metal nanoparticles 131 are ruthenium (Ru), atomic layer deposition of Ru nanoparticles on graphene 130G may be performed 5 times and 10 times, respectively, such that the resistivity of metal-doped graphene 130G-M may be reduced by about 60% and about 90%, respectively, compared to the resistivity of graphene 130.

A thickness of the buffer layer 130 may be, for example, less than about 10 nm, for example, in a range of about 0.3 nm to about 10 nm, in a range of about 0.3 nm to about 8 nm, in a range of about 0.3 nm to about 5 nm, in a range of about 0.3 nm to about 3 nm, in a range of about 0.5 nm to about 10 nm, in a range of about 0.5 nm to about 8 nm, in a range of about 0.5 nm to about 5 nm, or in a range of about 0.5 nm to about 3 nm.

The gate electrode 224 may be electrically connected to the word line 220 and may extend substantially perpendicular to the in-plane direction (e.g., xy direction) of the semiconductor substrate 210. The gate electrode 224 and the transistor channel 110T may face each other with the gate insulating film 240 interposed therebetween. The gate electrode 224 may include a low-resistance conductor, for example, Ti, TiN, TiON, or a combination thereof, but is not limited thereto. The gate electrode 224 may be formed of (or defined by) a single layer or two or more layers.

The gate insulating film 240 may be disposed between the gate electrode 224 and the transistor channel 110T, and may include a gate dielectric. The gate dielectric may include, for example, an oxide, a nitride, an oxynitride, or a combination thereof including silicon (Si), aluminum (Al), hafnium (Hf), lanthanum (Ra), zirconium (Zr), titanium (Ti), tantalum (Ta), yttrium (Y), barium (Ba), strontium (Sr), or an alloy thereof, but is not limited thereto.

The source electrode 273 and the drain electrode 275 may be disposed at the top and bottom (or on an upper and lower surfaces) of the transistor channel 110T. The source electrode 273 may be electrically connected to the capacitor 230 and the drain electrode 275 may be electrically connected to the bit line 120T. The drain electrode 275 may be defined by a portion of the bit line 120T overlapping the transistor channel 110T in a direction perpendicular to the in-plane direction (e.g., xy direction) of the semiconductor substrate 210.

Referring to FIGS. 5 and 6, the capacitor 230 may include electrodes (not shown) electrically connected to the source electrode 273 of the transistor 100T and a dielectric layer (not shown) disposed therebetween. The capacitor 230 may have a cylindrical shape extending perpendicularly to an in-plane direction (e.g., xy direction) of the semiconductor substrate 210, but is not limited thereto.

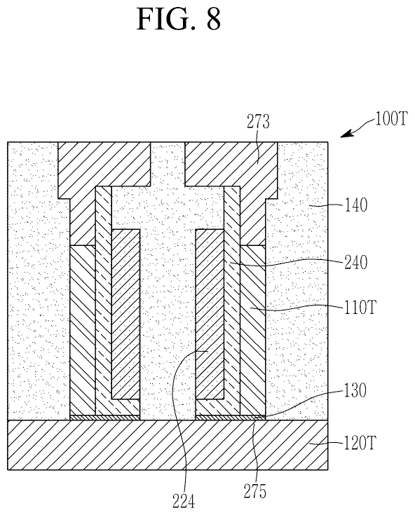

Referring to FIG. 8, the transistor 100T of the semiconductor device 1000 according to another embodiment includes the transistor channel 110T, the buffer layer 130, the gate electrode 224, the gate insulating film 240, the source electrode 273, and the drain electrode 275.

In such an embodiment, the buffer layer 130 is disposed between the gate insulating film 240 and the bit line 120T as well as between the transistor channel 110T and the bit line 120T. In an embodiment, for example, the upper surface of the buffer layer 130 may be in contact with the lower surface of the transistor channel 110T and the lower surface of the gate insulating film 240, while the lower surface of the buffer layer 130 may be in contact with the upper surface of the bit line 120T. In an embodiment, for example, the buffer layer 130 may be in contact with both of the lower surface of the transistor channel 110T and the lower surface of the gate insulating film 240.

The buffer layer 130 may block the oxide diffusion from oxide semiconductor between the transistor channel 110T and the bit line 120T to the bit line 120T and simultaneously, block the oxide diffusion from the gate insulating film 240 between the gate insulating film 240 and the bit line 120T to the bit line 120T to effectively prevent oxidation of the bit line 120T. Accordingly, the sharp increase in resistance due to the oxidation of the bit line 120T may be effectively prevented to effectively suppress or prevent electrical performance degradation of the semiconductor device 1000.

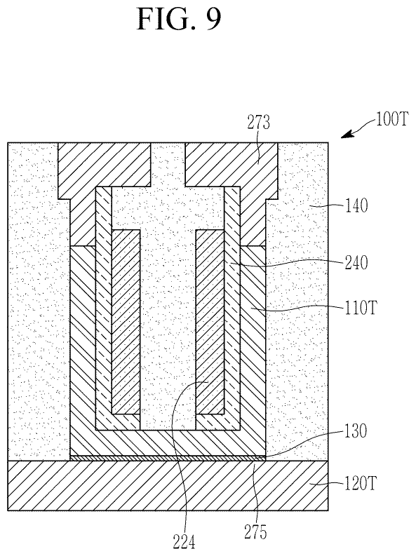

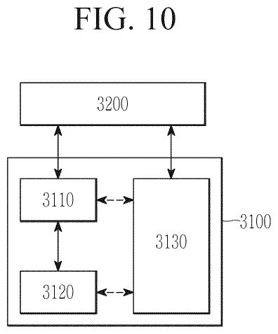

Referring to FIG. 9, the transistor 100T of the semiconductor device 1000 according to another embodiment includes the transistor channel 110T, the buffer layer 130, the gate electrode 224, the gate insulating film 240, the source electrode 273, and the drain electrode 275.

In such an embodiment, the transistor channels 110T in neighboring unit cells may be connected to one another, and the buffer layer 130 may be respectively in contact with the lower surface of the transistor channel 110T and the upper surface of the bit line 120T. In such an embodiment, where the transistor channel 110T and the bit line 120T have a relatively large contact area, the oxide diffusion may be effectively blocked by the buffer layer 130, accordingly, suppressing or preventing electrical performance degradation of the semiconductor device 1000.

Embodiments where the semiconductor device is a DRAM device are described above as an example, but the disclosure is not limited thereto and may be applied to a semiconductor device including a structure that an oxide and a conductive layer contact each other and/or all semiconductor devices including a vertical channel array transistor. For example, the semiconductor device may be used for arithmetic operation, program execution, and/or temporary data retention, etc.

Embodiments of the semiconductor device described above may be included in various electronic devices. The electronic devices may include, for example, mobile devices, computers, laptops, tablet computer, smart watches, sensors, digital cameras, electronic books, network devices, car navigators, Internet of Things (IoT), Internet of Everything (IoE), drones, door locks, safes, automated teller machines (ATM), security devices, medical devices, automobile electrical components, etc. but are not limited thereto.

FIG. 10 is a conceptual diagram showing an example of an electronic device according to an embodiment.

Referring to FIG. 10, the electronic device 3100 according to an embodiment may include a memory unit 3110, an arithmetic logic unit 3120, and a control unit 3130, which may be electrically connected to one another. In an embodiment, for example, the memory unit 3110, the arithmetic logic unit 3120, and the control unit 3130 may be implemented as one chip, for example, monolithically integrated on one substrate. The memory unit 3110, the arithmetic logic unit 3120, and the control unit 3130 may independently include the aforementioned semiconductor device 100 and 1000. The electronic device 3100 may be connected to one or more input/output devices 3200.

The disclosure should not be construed as being limited to the embodiments set forth herein. Rather, these embodiments are provided so that this disclosure will be thorough and complete and will fully convey the concept of the invention to those skilled in the art.

While the disclosure has been particularly shown and described with reference to embodiments thereof, it will be understood by those of ordinary skill in the art that various changes in form and details may be made therein without departing from the spirit or scope of the invention as defined by the following claims.

What is claimed is:

1. A semiconductor device comprising:
an oxide semiconductor layer comprising an oxide semiconductor;
a conductive layer; and
a buffer layer disposed between the oxide semiconductor layer and the conductive layer, wherein the buffer layer comprises graphene.

2. The semiconductor device of claim 1, wherein the buffer layer is in contact with a surface of the oxide semiconductor layer and a surface of the conductive layer, respectively.

3. The semiconductor device of claim 1, wherein the graphene comprises nanocrystalline graphene with a plurality of crystalline grains.

4. The semiconductor device of claim 1, wherein the buffer layer further comprises metal nanoparticles distributed in at least one selected from an upper portion, a lower portion, and an inner portion of the buffer layer.

5. The semiconductor device of claim 4, wherein each of the metal nanoparticles comprises at least one selected from ruthenium (Ru), aluminum (Al), copper (Cu), hafnium (Hf), iridium (Ir), rhodium (Rh), tungsten (W), molybdenum (Mo), titanium (Ti), tantalum (Ta), iron (Fe), cobalt (Co), iridium (Ir), palladium (Pd), platinum (Pt), and osmium (Os).

6. The semiconductor device of claim 1, wherein a thickness of the buffer layer is in a range of about 0.3 nm to about 5 nm.

7. The semiconductor device of claim 1, wherein the oxide semiconductor comprises an oxide comprising at least one selected from indium (In), zinc (Zn), gallium (Ga), and tin (Sn).

8. The semiconductor device of claim 1, wherein the conductive layer comprises at least one selected from tungsten (W), ruthenium (Ru), copper (Cu), molybdenum (Mo), aluminum (Al), Hafnium (Hf), cobalt (Co), titanium (Ti), tantalum (Ta), nickel (Ni), palladium (Pd), platinum (Pt), chromium (Cr), iron (Fe), rhodium (Rh), iridium (Ir), and osmium (Os).

9. The semiconductor device of claim 1, wherein
the semiconductor device comprises a transistor channel and a wire or electrode,
the transistor channel comprises the oxide semiconductor layer; and
the wire or electrode comprises the conductive layer.

10. A semiconductor device comprising:
a semiconductor substrate;
a transistor channel extending substantially perpendicular to an in-plane direction of the semiconductor substrate, wherein the transistor channel comprises an oxide semiconductor;
a bit line disposed under the transistor channel and electrically connected to the transistor channel; and
a buffer layer disposed between the transistor channel and the bit line, wherein the buffer layer comprises graphene.

11. The semiconductor device of claim 10, wherein the graphene comprises nanocrystalline graphene with a plurality of crystalline grains.

12. The semiconductor device of claim 10, wherein the buffer layer further comprises metal nanoparticles distributed in at least one selected from an upper portion, a lower portion, and an inner portion of the buffer layer.

13. The semiconductor device of claim 12, wherein each of the metal nanoparticles comprises at least one selected from ruthenium (Ru), aluminum (Al), copper (Cu), hafnium (Hf), iridium (Ir), rhodium (Rh), tungsten (W), molybdenum (Mo), titanium (Ti), tantalum (Ta), iron (Fe), cobalt (Co), iridium (Ir), palladium (Pd), platinum (Pt), and osmium (Os).

14. The semiconductor device of claim 10, wherein a thickness of the buffer layer is in a range of about 0.3 nm to about 5 nm.

15. The semiconductor device of claim 10, wherein the oxide semiconductor comprises an oxide comprising at least one selected from indium (In), zinc (Zn), gallium (Ga), and tin (Sn).

16. The semiconductor device of claim 10, wherein the bit line comprises at least one selected from tungsten (W), ruthenium (Ru), copper (Cu), molybdenum (Mo), aluminum (Al), Hafnium (Hf), cobalt (Co), titanium (Ti), tantalum (Ta), nickel (Ni), palladium (Pd), platinum (Pt), chromium (Cr), iron (Fe), rhodium (Rh), iridium (Ir), and osmium (Os).

17. The semiconductor device of claim 10, further comprising:
a word line disposed on the semiconductor substrate and extending in a direction different from an extending direction of the bit line;
a gate electrode electrically connected to the word line and extending substantially perpendicular to an in-plane direction of the semiconductor substrate; and
a gate insulating film between the gate electrode and the transistor channel.

18. The semiconductor device of claim 10, further comprising:
a capacitor disposed on the transistor channel and electrically connected to the transistor channel.

19. An electronic device comprising the semiconductor device of claim 1.

20. An electronic device comprising the semiconductor device of claim 10.
